(19) United States
(12) Patent Application Publication
(10) Pub. No.: US 2014/0144382 A1
(43) Pub. Date: May 29, 2014

(54) PLASMA APPARATUS

(71) Applicant: INDUSTRIAL TECHNOLOGY RESEARCH INSTITUTE, Hsinchu (TW)

(72) Inventors: Ming-Hsien Ko, Chiayi County (TW); Li-Wen Lai, Taichung City (TW); Kun-Wei Lin, Tainan City (TW); Chun-Hao Chang, Tainan City (TW); Tai-Hung Chen, Tainan City (TW)

(73) Assignee: INDUSTRIAL TECHNOLOGY RESEARCH INSTITUTE, Hsinchu (TW)

(21) Appl. No.: 13/726,658

(22) Filed: Dec. 26, 2012

(30) Foreign Application Priority Data
Nov. 27, 2012 (TW) 101144349

(51) Int. Cl. C23C 16/455

(52) U.S. Cl. CPC C23C 16/455
USPC 118/723 R

(57) ABSTRACT

A plasma apparatus including a chamber, an electrode set and a gas supplying tube set is provided. The chamber has a supporting table. The gas supplying tube set is disposed in the chamber and located between the supporting table and the electrode set. The gas supplying tube set includes at least one outer gas supplying tube and at least one first inner gas supplying tube. The first inner gas supplying tube is telescoped within the outer gas supplying tube. The outer gas supplying tube and the first inner gas supplying tube both have a plurality of gas apertures, and an amount of the gas apertures of the outer gas supplying tube is greater than an amount of the gas apertures of the first inner gas supplying tube.

### CROSS-REFERENCE TO RELATED APPLICATION

This application claims the priority benefit of Taiwan application serial no.

101144349, filed on Nov. 27, 2012. The entirety of the above-mentioned patent application is hereby incorporated by reference herein and made a part of this specification.

### BACKGROUND

1. Technical Field

The present proposal generally relates to an inductively coupled plasma (ICP) apparatus.

2. Description of Related Art

Plasma is ionized gas containing ions or electrodes and free radicals, which has a wide application. Plasma treatment refers to that the gas is transformed to the plasma, and the plasma gas is deposited on a substrate, or the plasma gas is used for cleaning, coating, sputtering, plasma chemical vapor deposition, ion implantation, ashing or etching, etc. During operation of a commonly used plasma treatment apparatus, after a powerful electric field is formed between two electrodes, the process gas supplied between the two electrodes is ionized or deionized to generate plasma.

Regarding a current research and development status of displays, large-scale displays and flexible displays are researched and developed, and during a commercialization process of the displays, a most important issue thereof is a high uniformity problem of a large area substrate. Regarding conventional capacitively coupled plasma (CCP), a processing rate of the apparatus cannot be effectively improved due to a small density of the plasma, so that inductively coupled plasma (ICP) becomes a technique with a great potential. Since a plasma density of the ICP is relatively high, the ICP is generally referred to as a high density plasma source, and a system thereof is characterized by an inductively coupled coil capable of generating plasma. However, a design of a large area ICP may have following problems: (1) when a length of the coil is excessively long to cause a problem of standing wave, efficiency of energy transfer is influenced; (2) in case of a large area, uniformity of the plasma is hard to be adjusted, especially at the part of a coil edge, processes such as plasma assisted deposition or plasma assisted etching are limited.

Conventionally, a diffusion plate is developed to bypass gas with ceramic balls, the process gas enters the diffusion plate from two sides of the chamber, so that the gas may be uniformly introduced into the chamber in cooperation with ICP coil to generate plasma. However, according to such method, a gas concentration at the gas-feed inlet is higher than a gas concentration at center.

Another conventional method provides a gas storage chamber around chamber walls and provides gas apertures on the gas storage chamber. The process gas is injected to a center of the chamber supplemented by showering gas from the gas apertures to a center of the chamber, and electric field is adjusted in cooperation with a coil and a magnet, such that a uniform film deposition may be formed. However, according to such method, film deposition thickness is not uniformity and is related to distances from the gas-feed inlet.

### SUMMARY

The present proposal is directed to a plasma apparatus including a chamber, an electrode set and a gas supplying tube set. The chamber has a supporting table. The gas supplying tube set is disposed in the chamber and located between the supporting table and the electrode set. The gas supplying tube set includes at least one outer gas supplying tube and at least one first inner gas supplying tube. The first inner gas supplying tube is telescoped within the outer gas supplying tube. The outer gas supplying tube and the first inner gas supplying tube both have a plurality of gas apertures, and an amount of the gas apertures of the outer gas supplying tube is greater than an amount of the gas apertures of the first inner gas supplying tube.

To make the above features and advantages of the present proposal more comprehensible, several embodiments accompanied with drawings are described in detail as follows.

### BRIEF DESCRIPTION OF THE DRAWINGS

FIG. 1 is an exterior view illustrating a plasma apparatus according to an embodiment of the present proposal.

FIG. 2 is a simplified and inverted cross-sectional view illustrating the plasma apparatus of FIG. 1 along the line A-A′.

FIG. 3 is a partial cross-sectional view illustrating a multilayer gas supplying tube of the plasma apparatus of FIG. 1.

FIG. 4 is an exterior view illustrating an electrode set of the plasma apparatus in FIG. 1.

FIG. 5A and FIG. 5B are cross-sectional views illustrating gas supplying tube sets of plasma apparatuses respectively according to another two embodiments of the present proposal.

FIG. 6A to FIG. 6D are film thickness simulations regarding film depositions of gas supplying tube sets respectively designed in single layer, double layer design, triple layer design and quadruple layer.

FIG. 7 is a cross-sectional view illustrating a plasma apparatus according to another embodiment of the invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The present proposal is directed to a plasma apparatus capable of maintaining a favorable film thickness uniformity in process of a large area.

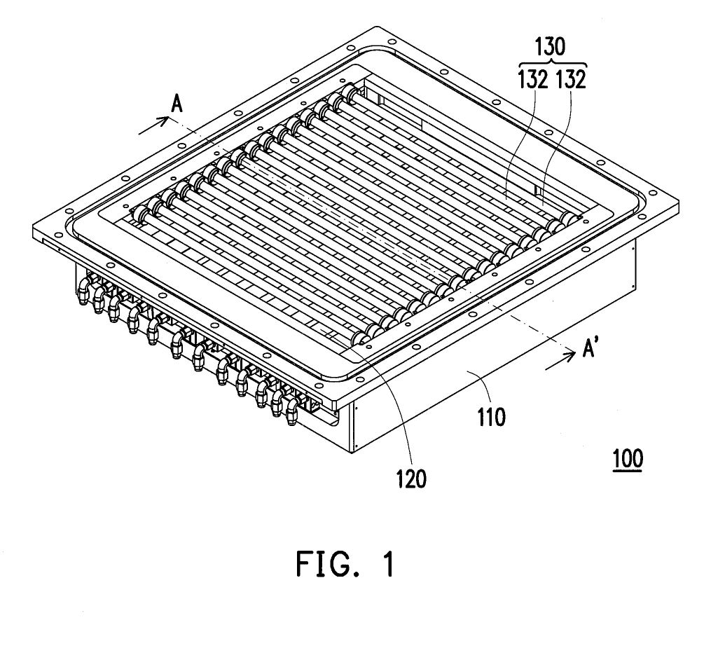

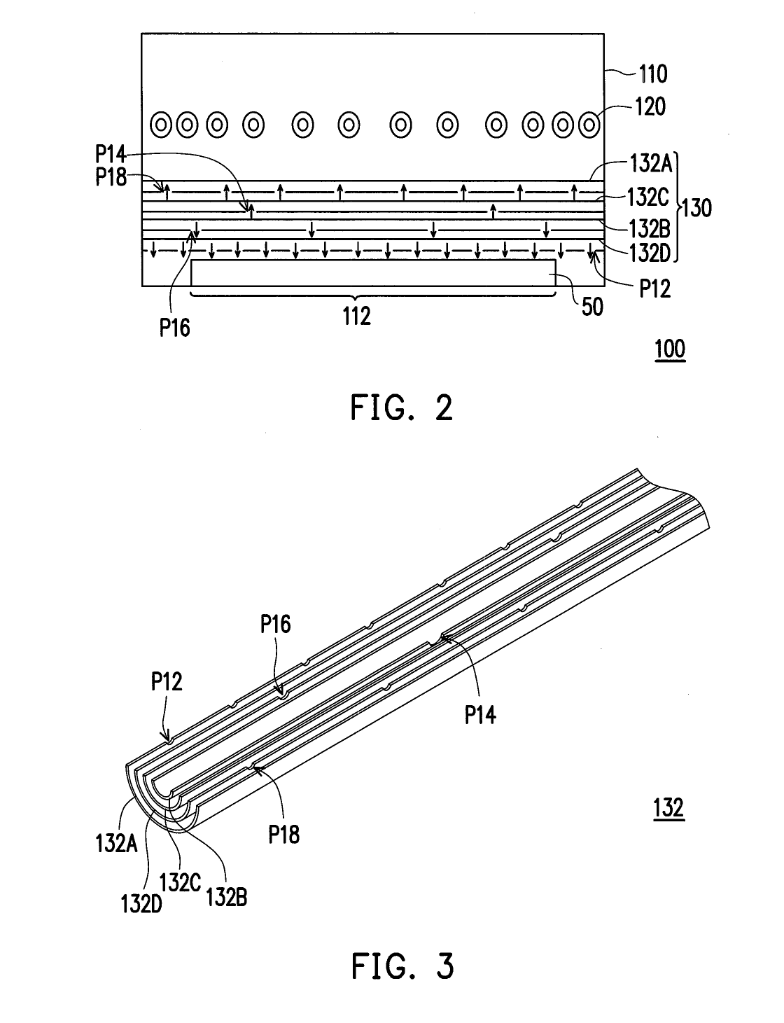

FIG. 1 is an exterior view illustrating a plasma apparatus according to an embodiment of the present proposal. FIG. 2 is a simplified and inverted cross-sectional view illustrating the plasma apparatus of FIG. 1 along the line A-A′. Referring to FIG. 1 and FIG. 2 together, a plasma apparatus 100 of the present embodiment includes a chamber 110, an electrode set 120 and a gas supplying tube set 130. The chamber 110 has a supporting table 112 for supporting a substrate 50. The gas supplying tube set 130 is disposed in the chamber 110 and located between the supporting table 112 and the electrode set 120.

According to the present embodiment, plasma is uniformed through a gas field generated by the gas supplying tube set 130 in the plasma apparatus 100, such that influences to complexity and costs of apparatus may be reduced accordingly. In addition, since the gas supplying tube set 130 is located between the supporting table 112 and the electrode set 120, most of the plasma that transformed from the process gas is directly moved to the substrate 50 instead of bombarding the electrode set 120. Therefore, less pollution particles may be produced, so as to increase process yield rate while reducing costs for cleaning the apparatus.

The gas supplying tube set 130 includes at least one outer gas supplying tube 132A and at least one first inner gas supplying tube 132B. The first inner gas supplying tube 132B is telescoped within the outer gas supplying tube 132A. In the present embodiment, the gas supplying tube set 130 includes a plurality of multilayer gas supplying tubes 132 arranged in parallel in the chamber 110. Each of the multilayer gas supplying tubes 132 includes one outer gas supplying tube 132A and one first inner gas supplying tube 132B. However, based on shape and dimension of the chamber 110, the gas supplying tube set 130 may also be composed by one single multilayer gas supplying tube 132. In addition, the multilayer gas supplying tube 132 may also be single multilayer gas supplying tube 132 being bended and distributed in the chamber 110. Hence, the gas supplying tube set of the present proposal may include single outer gas supplying tube and single first inner gas supplying tube. However, the gas supplying tube set of the proposal may include a plurality of outer gas supplying tubes and a plurality of first inner gas supplying tubes.

The outer gas supplying tube 132A has a plurality of gas apertures P12, and the first inner gas supplying tube 132B also has a plurality of gas apertures P14, and an amount of the gas apertures P12 of the outer gas supplying tube 132A is greater than an amount of the gas apertures P14 of the first inner gas supplying tube 132B.

According to the present embodiment, the gas apertures P12 and P14 are located above the supporting table 112 owing to the gas supplying tube set 130. The gas supplying tube set 130 passes through most parts of space within the chamber 110, which allows the gas apertures P12 and P14 of the gas supplying tube set 130 to be distributed in the space within the chamber 110, such that the gas field provided by the gas apertures P12 and P14 may be used to adjust uniformity of the plasma. When the supporting table 112 is supposed to provide a plane, an orthographic projection of at least most of the gas apertures P12 and P14 with respect to said plane falls within a range of the supporting table 112. During operation of the plasma apparatus 100 of the present embodiment, the process gas first enters the first inner gas supplying tube 132B, the process gas then enters between the first inner gas supplying tube 132B and the outer gas supplying tube 132A through the gas apertures P14 of the first inner gas supplying tube 132B. Next, the process gas is bypassed to enter the chamber 110 from the gas apertures P12 of the outer gas supplying tube 132A, such that an electric field generated by the electrode set 120 may ionize or dissociate the process gas to generate plasma. Since the amount of the gas apertures P12 of the outer gas supplying tube 132A is greater than the amount of the gas apertures P14 of the first inner gas supplying tube 132B, the process gas may be bypassed between the first inner gas supplying tube 132B and the outer gas supplying tube 132A before entering the chamber 110. This process may increase uniformity of gas introduction from gas apertures P12 of the outer gas supplying tube 132A, which allows maintaining a high uniformity of film deposition thickness on the substrate 50 having a large area.

In the present embodiment, the gas apertures P12 of the outer gas supplying tube 132A are facing towards the substrate 50, whereas the gas apertures P14 of the first inner gas supplying tube 132B are facing opposite to the substrate 50. Therefore, after exiting from the gas apertures P14 of the outer gas supplying tube 132B, the process gas first contacts a tube wall of outer gas supplying tube 132A. Next, after being bypassed and cycling the tube wall, the process gas reaches the gas apertures P12 of the outer gas supplying tube 132A on another side. This bypassing process as described above may facilitate the process gas to be distributed uniformly within the outer gas supplying tube 132A before entering the chamber 110 through the gas apertures P12 of the outer gas supplying tube 132A. The gas apertures P12 and P14 are vertical to an axial direction of the gas supplying tube set 130, and the gas apertures P12 and P14 may be disposed in different angles with the axial direction as a rotating center. That is to say, in the present embodiment, the gas apertures P12 are facing towards the supporting table 112 and the gas apertures P14 are facing opposite to the supporting table 112. However, according to other embodiments, the gas apertures P12 and P14 may also face towards other orientations, the present proposal is not limited thereto.

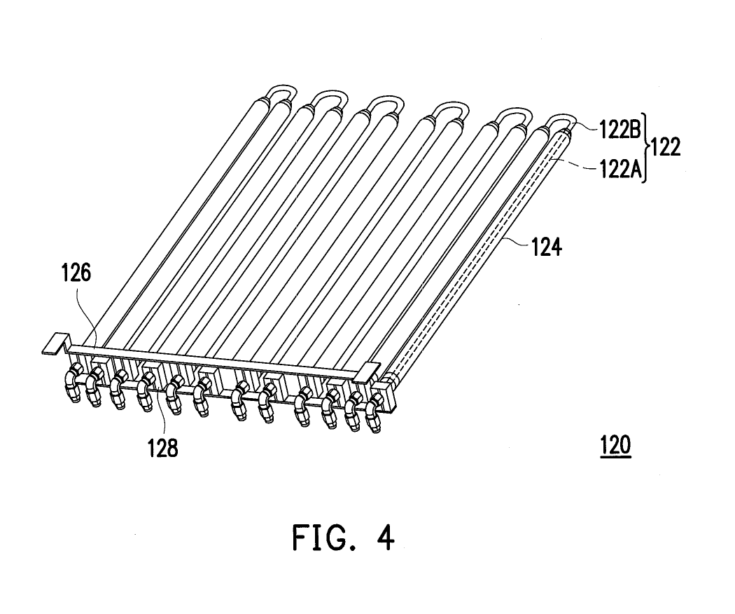

FIG. 3 is a partial cross-sectional view illustrating a multilayer gas supplying tube of the plasma apparatus of FIG. 1. Referring to FIG. 2 and FIG. 3 together, in the present embodiment, each of the multilayer gas supplying tubes 132 further includes a second inner gas supplying tube 132C and a third second inner gas supplying tube 132D. The second inner gas supplying tube 132C is telescoped between the outer gas supplying tube 132A and the first inner gas supplying tube 132B, whereas the third inner gas supplying tube 132D is telescoped between the outer gas supplying tube 132A and the second inner gas supplying tube 132C. The second inner gas supplying tube 132C has a plurality of gas apertures P16, and the third inner gas supplying tube 132D has a plurality of gas apertures P18. An amount of the apertures P16 of the second inner gas supplying tube 132C is within a range between the amount of the gas apertures P12 of the outer gas supplying tube 132A and the amount of the gas apertures P14 of the first inner gas supplying tube 132B, and an amount of the gas apertures P18 of the third inner gas supplying tube 132D is within a range between the amount of the gas apertures P12 of the outer gas supplying tube 132A and the amount of the gas apertures P16 of the second inner gas supplying tube 132C. The gas apertures P12 of the outer gas supplying tube 132A and the gas apertures P16 of the second inner gas supplying tube 132C are facing same direction, the gas apertures P18 of the third inner gas supplying tube 132D and the gas apertures P14 of the first inner gas supplying tube 132B are facing same direction, and the gas apertures P12 of the outer gas supplying tube 132A and the gas apertures P18 of the third inner gas supplying tube 132D are facing opposite directions. In other words, the process gas within the chamber 110 may be distributed more uniformly by having the process gas bypassed for a number of times within the multilayer gas supplying tube 132 before entering the chamber 110.

For instance, it is assumed that an amount of the gas apertures P12 is sixteen, an amount of the gas apertures P14 is two, an amount of the gas apertures P16 is four and an amount of the gas apertures P18 is eight. Each of the gas apertures P14 may be located between each two gas apertures P16, each of the gas apertures P16 may be located between each two gas apertures P18, and each of the gas apertures P18 may be located between each two gas apertures P12. Distances between the sixteen gas apertures P12 may be the same or different. Further, it can be known from FIG. 3, the gas apertures P12, P14, P16 and P18 are all located on a same plane, which is a cross-sectional plane of FIG. 3. Of course, as described above, the gas apertures P12, P14, P16 and P18 may be disposed in different angles with the axial direction of the multilayer gas supplying tubes 132 as the rotating center. According to an embodiment, in the case when a size of a horizontal plane of the chamber 110 is 600 mm×700 mm, pore sizes of the gas apertures P12, P14, P16 and P18 may be 2 mm or smaller.

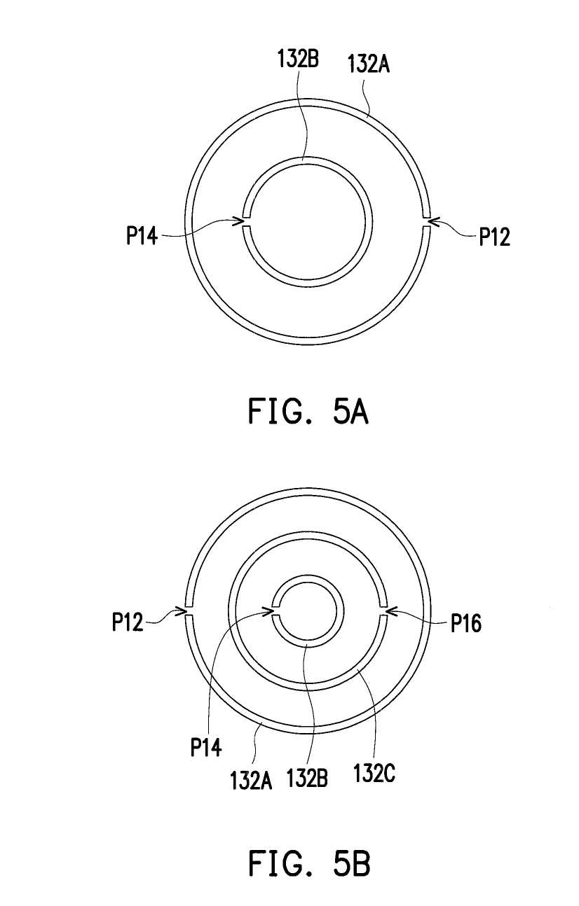

FIG. 4 is an exterior view illustrating an electrode set of the plasma apparatus in FIG. 1. Referring to FIG. 1 and FIG. 4 together, the electrode set 120 according to the present embodiment is partially located in the chamber 110. In addition, the electrode set 120 may include, for example, a metal body 122 and a plurality of dielectric sleeves 124, the dielectric sleeves 124 are telescoped on a portion of the metal body located in the chamber 110. The dielectric sleeves 124 are used to avoid the metal body 122 from damaged by plasma bombardment. The dielectric sleeves 124 may not be required when the electrode set 120 is completely located outside of the chamber 110. The metal body 122 may be made of, for example, copper, aluminum, stainless steel or other metals, whereas the dielectric sleeves 124 may be made of, for example, quartz or other dielectric materials. The metal body 122 of the electrode set 120 may include a plurality of linear bodies 122A and a plurality of first connecting portions 122B, and the electrode set 120 further includes a second connecting portion 126 and a third connecting portion 128. The linear bodies 122A are connected to each other in parallel, that is, each of the first connecting portions 122B is connected between two adjacent linear bodies 122A. Moreover, one end of each of a half of the linear bodies 122A that is not being connected to the first connecting portion 122B is connected to the second connecting portion 126 as to be grounded, and one end of each of another half of the linear bodies 122A that is not being connected to the first connecting portion 122B is connected to the third connecting portion 128 to be used as a power inlet.

In addition, referring to FIG. 1, each of the linear bodies 122A has a straight-line shape, and the linear bodies 122A are arranged in parallel to each other. An axial direction of the multilayer gas supplying tubes 132 of the gas supplying tube set 130 and an axial direction of the dielectric sleeves 124 of the electrode set 120 form a vertical angle. However, in other embodiments, the axial direction of the multilayer gas supplying tube 132 and the axial direction of the dielectric sleeves 124 may be parallel to one another or form other angles, the proposal is not limited thereto. Referring to FIG. 4, a distance between the linear bodies 122A arranged on a middle section is greater than a distance between the linear bodies 122A arranged on two side sections. More specifically, the closer the linear bodies 122A are to the walls of the chamber 110, the smaller the distance between two adjacent linear bodies 122A may become. A favorable uniformity of film deposition thickness may be obtained when the linear bodies 122A are arranged according to above-said method.

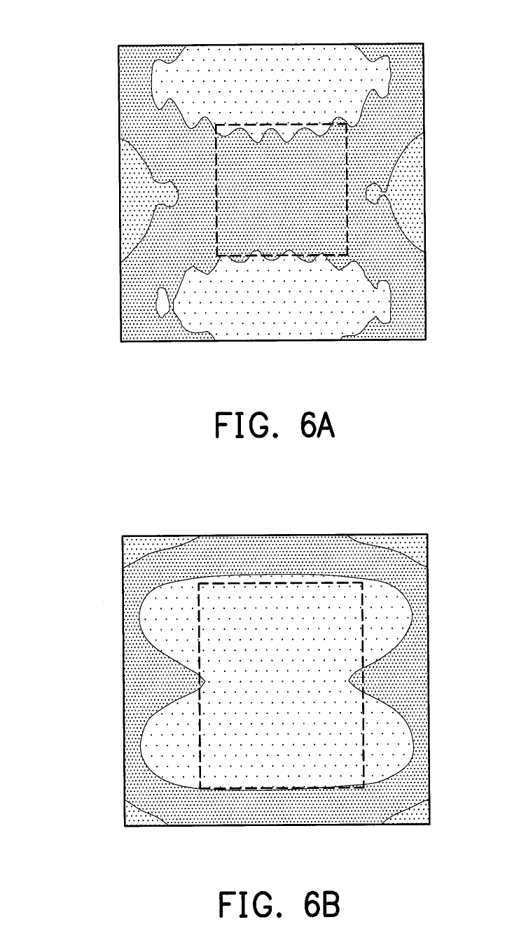

FIG. 5A and FIG. 5B are cross-sectional views illustrating gas supplying tube sets of plasma apparatuses respectively according to another two embodiments of the present proposal. Referring to FIG. 5A, the gas supplying tube set of the present embodiment is a double layer design, which only includes the outer gas supplying tube 132A and the first inner gas supplying tube 132B. The outer gas supplying tube 132A has sixteen gas apertures P12, and the first inner gas supplying tube 132B has two gas apertures P14. In which, the gas apertures P12 of the outer gas supplying tube 132A and the gas apertures P14 of the first inner gas supplying tube 132B are facing opposite directions. Referring to FIG. 5B, the gas supplying tube set of the present embodiment is a triple layer design, which includes the outer gas supplying tube 132A, the first inner gas supplying tube 132B and the second inner gas supplying tube 132C. The outer gas supplying tube 132A has sixteen gas apertures P12, the first inner gas supplying tube 132B has two gas apertures P14 and the second inner gas supplying tube 132C has four gas apertures P16. In which, the gas apertures P12 of the outer gas supplying tube 132A and the gas apertures P14 of the first inner gas supplying tube 132B are facing same direction, the gap apertures P12 of the outer gas supplying tube 132A and the gas apertures P16 of the second inner gas supplying tube 132C are facing opposite directions. The gas supplying tube set of the plasma apparatus of the present proposal may be designed in double layer, triple layer and quadruple layer or with even more layers.

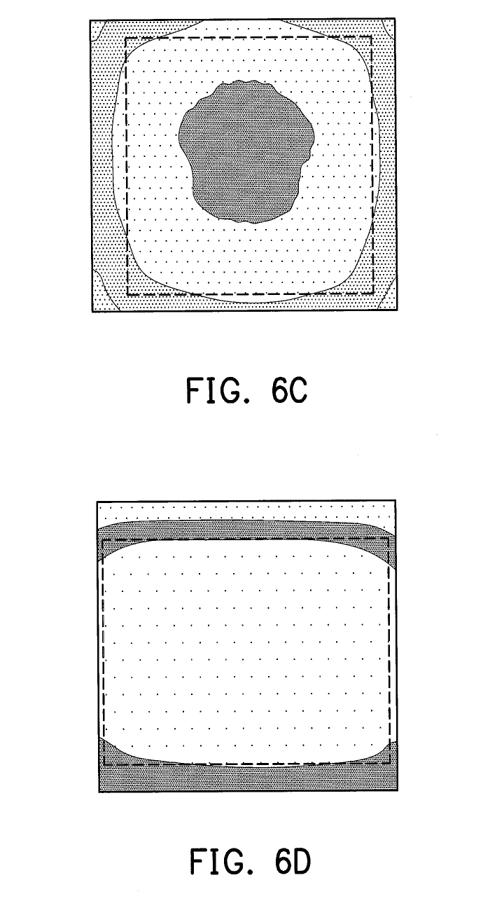

FIG. 6A to FIG. 6D are film thickness simulations regarding film depositions of gas supplying tube sets respectively designed in single layer, double layer design, triple layer design and quadruple layer. FIG. 6A illustrates a film deposition to a gas supplying tube set with a conventional single layer design, in case when a size of the horizontal plane of the chamber 110 is 600 mm×700 mm, a size of a region with uniform film thickness is approximately 200 mm×200 mm. FIG. 6B illustrates a film deposition to a gas supplying tube set with the double layer design as shown in FIG. 5A, in case when a size of the horizontal plane of the chamber 110 is 600 mm×700 mm, a size of a region with uniform film thickness is increased to approximately 300 mm×400 mm. FIG. 6C illustrates a film deposition to a gas supplying tube set with the triple layer design as shown in FIG. 5B, in case when a size of the horizontal plane of the chamber 110 is 600 mm×700 mm, a size of a region with uniform film thickness is increased to approximately 400 mm×500 mm. FIG. 6D illustrates a film deposition to a gas supplying tube set with the quadruple layer design as shown in FIG. 3, in case when a size of the horizontal plane of the chamber 110 is 600 mm×700 mm, a size of a region with uniform film thickness is increased to approximately 500 mm×500 mm. In view of the above simulation results, it can be known that the gas supplying tube set with multilayer design in the present proposal may substantially increase uniformity of film deposition thickness on a large area substrate.

Other embodiments are described to illustrate the invention more clearly in the following. It should be noted that the reference numerals and a part of the contents in the previous embodiment are used in the following embodiments, in which identical reference numerals indicate identical or similar components, and repeated description of the same technical contents is omitted. For a detailed description of the omitted parts, reference can be found in the previous embodiment, and no repeated description is contained in the following embodiments.

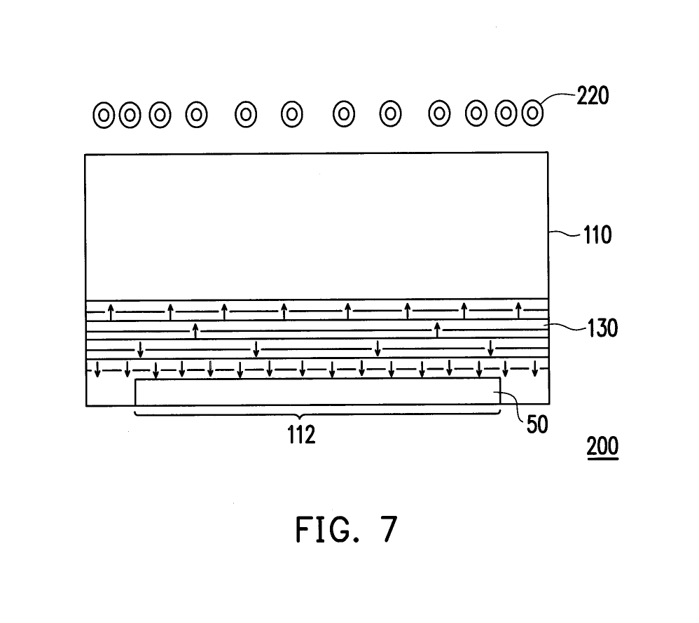

FIG. 7 is a cross-sectional view illustrating a plasma apparatus according to another embodiment of the invention. Referring to FIG. 7, a plasma apparatus 200 of the present embodiment is similar to the plasma apparatus 100 of FIG. 2, the difference thereof lies where an electrode set 220 is located outside of the chamber 110. Since the gas supplying tube set 130 is still located between the supporting table 112 and the electrode set 220, the gas field provided by the gas apertures may still be used to uniformly apply the plasma onto the substrate 50. Moreover, the plasma apparatus 200 of the present embodiment also uses the gas supplying tube set 130 with multilayer design, which may substantially increase uniformity of film deposition thickness on a large size substrate.

In the plasma apparatus of the present proposal, the gas supplied from multilayer gas supplying tubes may be bypassed and uniformly distributed into the chamber, so as to obtain a uniform film deposition thickness.

Based on above, the present proposal provides a plasma apparatus with the multilayer gas supplying tubes. After being introduced from the inner tubes of the gas supplying tube, the process gas may first be bypassed before entering the chamber through the outer tube to be uniformly distributed within the chamber. As a result, plasma generated by exciting the process gas may also be uniformly distributed within the chamber, such that a uniform film deposition thickness may be obtained on the substrate.

Although the present proposal has been described with reference to the above embodiments, it is apparent to one of the ordinary skill in the art that modifications to the described embodiments may be made without departing from the spirit of the present proposal. Accordingly, the scope of the present proposal will be defined by the attached claims not by the above detailed descriptions.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A plasma apparatus, comprising:
a chamber having a supporting table;
an electrode set; and
a gas supplying tube set disposed in the chamber and located between the supporting table and the electrode set, wherein the gas supplying tube set comprises at least one outer gas supplying tube and at least one first inner gas supplying tube, the first inner gas supplying tube is telescoped within the outer gas supplying tube, the outer gas supplying tube and the first inner gas supplying tube both have a plurality of gas apertures, and an amount of the gas apertures of the outer gas supplying tube is greater than an amount of the gas apertures of the first inner gas supplying tube.

2. The plasma apparatus of claim 1, wherein the gas apertures of the outer gas supplying tube and the gas apertures of the first inner gas supplying tube are facing opposite directions.

3. The plasma apparatus of claim 1, wherein the gas apertures of the outer gas supplying tube and the gas apertures of the first inner gas supplying tube are located on a same plane.

4. The plasma apparatus of claim 1, wherein the gas apertures are vertical to an axial direction of the gas supplying tube set, and the gas apertures may be disposed in different angles with the axial direction as a rotating center.

5. The plasma apparatus of claim 1, wherein the gas supplying tube set comprises a plurality of multilayer gas supplying tubes arranged in parallel in the chamber, each of the multilayer gas supplying tubes comprises one of the at least one outer gas supplying tube and one of the at least one inner gas supplying tube.

6. The plasma apparatus of claim 1, wherein the gas supplying tube set further comprises a second inner gas supplying tube, the second inner gas supplying tube is telescoped between the outer gas supplying tube and the first inner gas supplying tube, the second inner gas supplying tube has a plurality of gas apertures, and an amount of the gas apertures of the second inner gas supplying tube is within a range between the amount of the gas apertures of the outer gas supplying tube and the amount of the gas apertures of the first inner gas supplying tube.

7. The plasma apparatus of claim 6, wherein the gas apertures of the outer gas supplying tube and the gas apertures of the first inner gas supplying tube are facing same direction, and the gas apertures of the outer gas supplying tube and the gas apertures of the second inner gas supplying tube are facing opposite directions.

8. The plasma apparatus of claim 6, wherein the gas supplying tube set further comprises a third inner gas supplying tube, the third inner gas supplying tube is telescoped between the outer gas supplying tube and the second inner gas supplying tube, the third inner gas supplying tube has a plurality of gas apertures, and an amount of the gas apertures of the third inner gas supplying tube is within a range between the amount of the apertures of the outer gas supplying tube and the amount of the apertures of the second inner gas supplying tube.

9. The plasma apparatus of claim 8, wherein the gas apertures of the outer gas supplying tube and the gas apertures of the second inner gas supplying tube are facing same direction, the gas apertures of the third gas supplying tube and the gas apertures of the first inner gas supplying tube are facing same direction, and the gas apertures of the outer gas supplying tube and the gas apertures of the third inner gas supplying tube are facing opposite directions.

10. The plasma apparatus of claim 1, wherein the electrode set is partially located in the chamber.

11. The plasma apparatus of claim 10, wherein the electrode set comprises a metal body and a plurality of dielectric sleeves, the dielectric sleeves are telescoped on a portion of the metal body located in the chamber.

12. The plasma apparatus of claim 1, wherein the electrode set is located outside of the chamber.

13. The plasma apparatus of claim 1, wherein the electrode set comprises:
a plurality of linear bodies; and
a plurality of connecting portions connecting two adjacent linear bodies;
wherein, the linear bodies are connected to each other in parallel.

14. The plasma apparatus of claim 13, wherein each of the linear bodies has a straight-line shape.

15. The plasma apparatus of claim 13, wherein the linear bodies are arranged in parallel to each other, a distance between the linear bodies arranged on a middle section is greater than a distance between the linear bodies arranged on two side sections.
